(19) United States
(12) Patent Application Publication
(10) Pub. No.: US 2025/0131153 A1
(43) Pub. Date: Apr. 24, 2025

(54) METHOD AND APPARATUS OF INFORMATION EXCHANGE FOR DIGITAL TWIN FEDERATION

(71) Applicant: ELECTRONICS AND TELECOMMUNICATIONS RESEARCH INSTITUTE, Daejeon (KR)

(72) Inventors: Hyun Jeong LEE, Daejeon (KR); Chang Kyu LEE, Daejeon (KR); Shin Gak KANG, Daejeon (KR)

(21) Appl. No.: 18/493,967

(22) Filed: Oct. 25, 2023

(30) Foreign Application Priority Data
Oct. 24, 2023 (KR) 10-2023-0143317

(51) Int. Cl. G06F 30/20

(52) U.S. Cl. CPC G06F 30/20

(57) ABSTRACT

The present invention relates to an information exchange method and device for digital twin federation. A method for transmitting and receiving information for digital twin federation by digital twin according to an embodiment of the present invention may comprise: transmitting a message related to the digital twin federation to a component of the digital twin federal; and receiving a response to the message. Herein, the component of the digital twin federation may correspond to one or more of another digital twin, a registry, or a communication adapter. The message may include a header area and a data area, and the data area may include object information related to at least one of the digital twin or the component of the digital twin federation and action information indicating an operation related to the digital twin federation.

### CROSS-REFERENCE TO RELATED APPLICATION

This application claims the benefit of earlier filing date and right of priority to Korean Application No. 10-2023-0143317, filed on Oct. 24, 2023, the contents of which are all hereby incorporated by reference herein in their entirety.

### BACKGROUND

### 1. Technical Field

The present disclosure relates to a method and apparatus for exchanging information for digital twin federation, and specifically relates to a method and apparatus for information exchange between digital twin components to provide new services across multiple domains through digital twin federation.

### 2. Description of Related Art

Digital twins are used in each domain, including manufacturing, city, home, energy, and medical fields.

However, the existing digital twin method has the problem of difficult to identify which digital twin functions and services exist in which field, and when providing new digital twin functions and services, there is the problem of having to develop them from scratch, inconvenience and cost loss.

### SUMMARY

The technical object of the present disclosure is to provide a method and apparatus for exchanging information for digital twin federation.

The technical object of the present disclosure is to provide a method and apparatus for exchanging information between digital twin components to provide, through a digital twin federation, new services across multiple domains, such as registering feature information between components such as digital twins, registries, and communication adapters for digital twin federation, searching digital twins for federation targets, establishing connections, and exchanging information.

The technical object of the present disclosure is to provide a method and apparatus for exchanging information for digital twin federation to provide a new service, by sharing data and functions by combining two or more digital twins used in each domain such as manufacturing, city, home, energy, and medical fields.

The technical objects to be achieved by the present disclosure are not limited to the above-described technical objects, and other technical objects which are not described herein will be clearly understood by those skilled in the pertinent art from the following description.

A method of transmitting and receiving information for a digital twin federation by a digital twin according to an aspect of the present disclosure may comprise: transmitting a message related to the digital twin federation to a component of the digital twin federal; and receiving a response to the message. Herein, the component of the digital twin federation may correspond to one or more of another digital twin, a registry, or a communication adapter. The message may include a header area and a data area, and the data area may include object information related to at least one of the digital twin or the component of the digital twin federation and action information indicating an operation related to the digital twin federation.

An apparatus for transmitting and receiving information for a digital twin federation by a digital twin according to an additional aspect of the present disclosure may comprise a processor and a memory, the processor may be configured to: transmit a message related to the digital twin federation to a component of the digital twin federal; and receive a response to the message. Herein, the component of the digital twin federation may correspond to one or more of another digital twin, a registry, or a communication adapter. The message may include a header area and a data area, and the data area may include object information related to at least one of the digital twin or the component of the digital twin federation and action information indicating an operation related to the digital twin federation.

As one or more non-transitory computer readable media storing one or more instructions according to an additional aspect of the present disclosure, the one or more instructions may be executed by one or more processors and control an apparatus for processing hologram to: transmit a message related to the digital twin federation to a component of the digital twin federal; and receive a response to the message. Herein, the component of the digital twin federation may correspond to one or more of another digital twin, a registry, or a communication adapter. The message may include a header area and a data area, and the data area may include object information related to at least one of the digital twin or the component of the digital twin federation and action information indicating an operation related to the digital twin federation.

In various aspects of the present disclosure, the digital twin federation may be based on sharing one or more of data or a function between the digital twin and the another digital twin.

Additionally, in various aspects of the present disclosure, the header area may include at least one of sender identification information, receiver identification information, or creation time-related information for the message.

Additionally, in various aspects of the present disclosure, the action information may indicate one of the action list predefined for the digital twin federation. In this regard, the predefined action list may include one or more of 1) request for change of existing data, 2) request for connecting for digital twin federation, 3) request for deleting of existing data, 4) request for sharing data, 5) request for processing function, 6) request for registering data, 7) a response, or 8) publishing of changes to information.

Additionally, in various aspects of the present disclosure, the object information may include information on attributes for objects related to the digital twin federation. In this regard, the attributes for the object may include one or more of 1) name of an object, 2) identification information of an object, 3) description of an object, 4) notation formation for an object, 5) function property, 6) data property, 7) content type, or 8) access-related information.

Additionally, in various aspects of the present disclosure, when the message corresponds to a message for registering feature information of the digital twin with the registry, the message may be transmitted to the registry. In contrast, when the message corresponds to a message for registering feature information of the digital twin to the another digital twin, the message may be transmitted to the another digital twin.

Additionally, in various aspects of the present disclosure, when the message corresponds to a message for discovering members for the digital twin federation, the message may be set to request information on a digital twin with one or more of specific data, a specific function, or specific performance and is sent to the registry. At this time, the response may include identification information on the digital twin with one or more of specific data, a specific function, or specific performance.

Additionally, in various aspects of the present disclosure, when the message corresponds to a message for establishing a connection or data and function processing with the other digital twin, and direct communication between the digital twin and the other digital twin is possible, the message may be transmitted to the another digital twin. In contrast, when the message corresponds to a message for establishing a connection or data and function processing with the other digital twin, and direct communication between the digital twin and the another digital twin is impossible, the message may be transmitted to the communication adapter and transferred to the another digital twin.

Additionally, in various aspects of the present disclosure, the response may include one or more of 1) information for identifying an operation based on the message, or 2) information on a result of the operation and the number of objects according to the object information.

According to the present disclosure, a method and apparatus for exchanging information for digital twin federation may be provided.

According to the present disclosure, a method and apparatus for exchanging information between digital twin components to provide, through a digital twin federation, new services across multiple domains, such as registering feature information between components such as digital twins, registries, and communication adapters for digital twin federation, searching digital twins for federation targets, establishing connections, and exchanging information may be provided.

According to the present disclosure, a method and apparatus for exchanging information for digital twin federation to provide a new service, by sharing data and functions by combining two or more digital twins used in each domain such as manufacturing, city, home, energy, and medical fields may be provided.

Effects achievable by the present disclosure are not limited to the above-described effects, and other effects which are not described herein may be clearly understood by those skilled in the pertinent art from the following description.

### BRIEF DESCRIPTION OF THE DRAWINGS

FIG. 1 illustrates a conceptual diagram of digital twin federation according to an embodiment of the present disclosure.

FIG. 2 illustrates the structure of messages exchanged between main components for digital twin federation according to an embodiment of the present disclosure.

FIG. 3 illustrates a procedure for registering feature information between a digital twin and a registry according to an embodiment of the present disclosure.

FIG. 4 illustrates a procedure for registering feature information between digital twins according to an embodiment of the present disclosure.

FIG. 5 illustrates a procedure for discovering members of a digital twin federation according to an embodiment of the present disclosure.

FIG. 6 illustrates a procedure for establishing a direct connection between digital twins according to an embodiment of the present disclosure.

FIG. 7 illustrates a procedure for establishing an indirect connection using a communication adapter between digital twins according to an embodiment of the present disclosure.

FIG. 8 illustrates a direct information exchange procedure between digital twins according to an embodiment of the present disclosure.

FIG. 9 illustrates an indirect information exchange procedure for converting content types between digital twins according to an embodiment of the present disclosure.

FIG. 10 illustrates an XML schema diagram of a message structure according to an embodiment of the present disclosure.

FIG. 11 illustrates an XML schema of a message structure according to an embodiment of the present disclosure.

FIG. 12 illustrates an operational flowchart of a method for exchanging digital twin association information according to an embodiment of the present disclosure.

FIG. 13 is a block diagram illustrating an apparatus according to an embodiment of the present disclosure.

### DETAILED DESCRIPTION

As the present disclosure may make various changes and have multiple embodiments, specific embodiments are illustrated in a drawing and are described in detail in a detailed description. But, it is not to limit the present disclosure to a specific embodiment, and should be understood as including all changes, equivalents and substitutes included in an idea and a technical scope of the present disclosure. A similar reference numeral in a drawing refers to a like or similar function across multiple aspects. A shape and a size, etc. of elements in a drawing may be exaggerated for a clearer description. A detailed description on exemplary embodiments described below refers to an accompanying drawing which shows a specific embodiment as an example. These embodiments are described in detail so that those skilled in the pertinent art can implement an embodiment. It should be understood that a variety of embodiments are different each other, but they do not need to be mutually exclusive. For example, a specific shape, structure and characteristic described herein may be implemented in other embodiment without departing from a scope and a spirit of the present disclosure in connection with an embodiment. In addition, it should be understood that a position or an arrangement of an individual element in each disclosed embodiment may be changed without departing from a scope and a spirit of an embodiment. Accordingly, a detailed description described below is not taken as a limited meaning and a scope of exemplary embodiments, if properly described, are limited only by an accompanying claim along with any scope equivalent to that claimed by those claims.

In the present disclosure, a term such as first, second, etc. may be used to describe a variety of elements, but the elements should not be limited by the terms. The terms are used only to distinguish one element from other element. For example, without getting out of a scope of a right of the present disclosure, a first element may be referred to as a second element and likewise, a second element may be also referred to as a first element. A term of and/or includes a combination of a plurality of relevant described items or any item of a plurality of relevant described items.

When an element in the present disclosure is referred to as being “connected” or “linked” to another element, it should be understood that it may be directly connected or linked to that another element, but there may be another element between them. Meanwhile, when an element is referred to as being “directly connected” or “directly linked” to another element, it should be understood that there is no another element between them.

As construction units shown in an embodiment of the present disclosure are independently shown to represent different characteristic functions, it does not mean that each construction unit is composed in a construction unit of separate hardware or one software. In other words, as each construction unit is included by being enumerated as each construction unit for convenience of a description, at least two construction units of each construction unit may be combined to form one construction unit or one construction unit may be divided into a plurality of construction units to perform a function, and an integrated embodiment and a separate embodiment of each construction unit are also included in a scope of a right of the present disclosure unless they are beyond the essence of the present disclosure.

A term used in the present disclosure is just used to describe a specific embodiment, and is not intended to limit the present disclosure. A singular expression, unless the context clearly indicates otherwise, includes a plural expression. In the present disclosure, it should be understood that a term such as “include” or “have”, etc. is just intended to designate the presence of a feature, a number, a step, an operation, an element, a part or a combination thereof described in the present specification, and it does not exclude in advance a possibility of presence or addition of one or more other features, numbers, steps, operations, elements, parts or their combinations. In other words, a description of “including” a specific configuration in the present disclosure does not exclude a configuration other than a corresponding configuration, and it means that an additional configuration may be included in a scope of a technical idea of the present disclosure or an embodiment of the present disclosure.

Some elements of the present disclosure are not a necessary element which performs an essential function in the present disclosure and may be an optional element for just improving performance. The present disclosure may be implemented by including only a construction unit which is necessary to implement essence of the present disclosure except for an element used just for performance improvement, and a structure including only a necessary element except for an optional element used just for performance improvement is also included in a scope of a right of the present disclosure.

Hereinafter, an embodiment of the present disclosure is described in detail by referring to a drawing. In describing an embodiment of the present specification, when it is determined that a detailed description on a relevant disclosed configuration or function may obscure a gist of the present specification, such a detailed description is omitted, and the same reference numeral is used for the same element in a drawing and an overlapping description on the same element is omitted.

As mentioned above, existing digital twins are used in each domain such as manufacturing, city, home, energy, and medical fields, but It is difficult to determine which digital twin functions and services exist in which field, and when providing new digital twin functions and services, there is a problem of having to develop them from scratch, resulting in inconvenience and cost loss.

In order to solve this problem, the method proposed in the present disclosure relates to a method for registering, searching, and managing (modify, delete) feature information describing the data, functions, and performance of the digital twin, searching for an appropriate digital twin, and establishing connections and exchanging information between digital twins.

Through the method proposed in the present disclosure, Data, functions, and performance between digital twins may be easily registered, searched, and utilized (in the same way as an app store), expand existing digital twin capabilities and services, or two or more digital twins may be combined to form a new service (e.g., Digital twin as a service).

To accomplish this, technologies for information exchange between digital twin components may be required to provide new services across multiple domains through digital twin federation, such as search for digital twins, connection establishment, and information exchange, including data and functions of digital twins.

Hereinafter, in the present disclosure, the information exchange method and device for digital twin federation as described above will be described through specific examples.

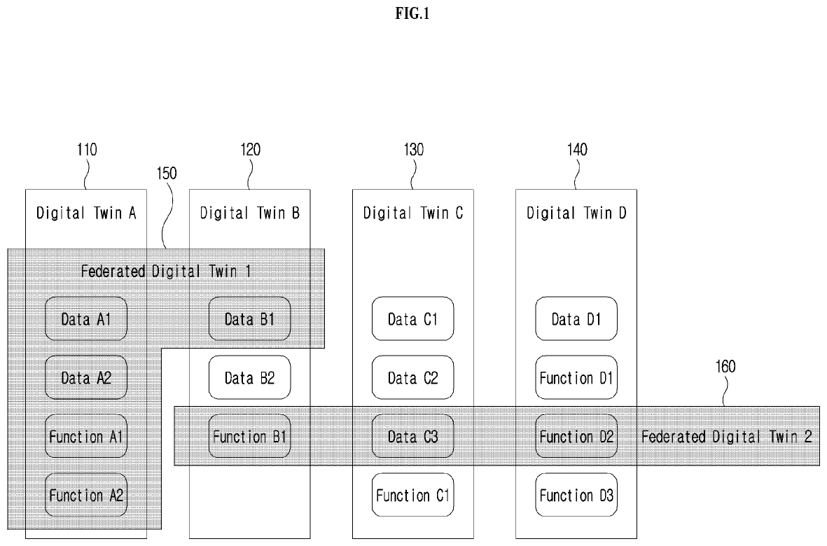

FIG. 1 illustrates a conceptual diagram of digital twin federation according to an embodiment of the present disclosure.

Referring to FIG. 1, each digital twin may provide new services across multiple domains through a digital twin federation (i.e., federated digital twin) that shares data and functions with other digital twins.

In this regard, in each application domain, a digital twin may include data collected, managed, and utilized, and functions and performance provided.

For example, digital twin A 110 (e.g., DT-001) may include data A1 and data A2, and may provide function A1 and function A2. Digital twin B 120 (e.g., DT-002) may include data B1 and data B2, and may provide function B1. Digital twin C 130 (e.g., DT-003) may include data C1, data C2, and data C3, and may provide function C1. Digital twin D 140 (e.g., DT-004) may include data D1 and may provide function D1, function D2, and function D3.

Referring to FIG. 1, federated digital twin 1 (150) may combine data A1, data A2, function A1, and function A2 contained in digital twin A (110) and data B1 contained in digital twin B (120), and provide new services. Additionally, federated digital twin 2 (160) may combine function B1 contained in digital twin B (120), data C3 contained in digital twin C (130), and function D2 contained in digital twin D (140), and provide new services.

That is, through a federated digital twin based on multiple digital twins, new services that cannot be provided by existing digital twins (e.g., digital twin A (110), digital twin B (120), digital twin C (130), and digital twin D (140), etc. may be provided.

The above-described digital twin federation may consist of three main components: digital twin, registry, and communication adapter.

The digital twin corresponds to the main component of the digital twin federation that provides independent applications, and may provide federated applications.

The registry may register feature information of the digital twin and provide the registered feature information according to a search request for the digital twin. In this regard, if the digital twin(s) for performing digital twin federation are determined/set in advance, registration and search through the registry may be unnecessary.

The communication adapter may be used to establish an indirect connection between digital twins when a direct connection may not be established.

A federated digital twin is an entity created as a result of the above-described digital twin federation, and may be the same as an extension of the digital twin that started the digital twin federation.

As an example, federated digital twin 1 in FIG. 1 may correspond to an extension of digital twin A (110) utilizing data of digital twin B (120).

The basic behavior between the components for federation of digital twins, i.e. digital twin, registry, and/or communication adapters, may be as follows.
1) Feature information registration
2) Federation member discovery
3) Connection establishment
4) Information exchange

First, the feature information registration may correspond to an operation for the digital twin to register feature information.

For example, an operation for a digital twin to register feature information in a registry may be considered.

For another example, when a digital twin is associated with a pre-planned/set digital twin, an operation to register feature information between the digital twins may be considered.

Next, the federation member discovery may correspond to an operation for the digital twin to discover and select a digital twin with the necessary data and functions in the registry. If there is a pre-planned/set participating digital twin, the operation of the federation member discovery may be unnecessary.

Next, Connection establishment may correspond to an operation for the digital twin initiating a digital twin federation (i.e., the initiating digital twin) to establish direct communication with the digital twin participating in the digital twin federation (i.e., the participating digital twin).

Regarding connection establishment, a direct connection establishment operation performed through direct communication between digital twins and an indirect connection establishment operation performed when direct communication between digital twins is not possible may be considered.

For example, direct connection establishment may be performed if the initiating digital twin uses the same communication protocol and data format as the participating digital twin and policy allows direct communication.

In this regard, the initiating digital twin may transmit a connection request to the participating digital twin. If the participating digital twin accepts the connection request, a connection for direct communication can be established.

As another example, indirect connection establishment may be performed when the initiating digital twin uses a different communication protocol and data format than the participating digital twin, or when direct communication is not possible due to policy.

In this regard, the initiating digital twin may transmit a connection request containing information of the participating digital twin to the participating digital twin through a communication adapter. If the participating digital twin accepts the connection request, an indirect connection can be established through a communication adapter.

Next, information exchange may correspond to operations for sharing data and functions between digital twins.

For example, direct information exchange may be performed for the initiating digital twin to share data and functional results with the participating digital twins through a direct connection.

As another example, indirect information exchange may be performed for an initiating digital twin to share data and functional results with a participating digital twin through an indirect connection via a communication adapter.

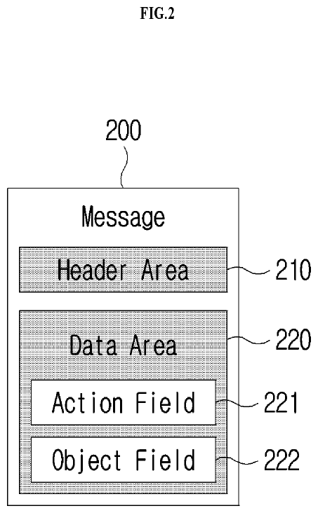

FIG. 2 illustrates the structure of messages exchanged between main components for digital twin federation according to an embodiment of the present disclosure.

Referring to FIG. 2, the message may include a header area 210 containing information for communication (e.g., information for identifying the message) and data area 220 containing action/object related information.

Specifically, the data area 220 may include an action field 221 indicating information on the performed operation and response and an object field 222 indicating the object that is the target of the corresponding action and response.

The header area 210 may include a sender, a receiver, time, etc.

The sender may request an action from the receiver.

Table 1 illustrates the attributes of the sender in the header area in the messages exchanged for digital twin federation.

TABLE 1

| Attribute | Description | Examples |
|---|---|---|
| Sender | A value used to uniquely identify | telnet://192.0.2.17:80/ |
| ID | a sender (e.g., URI(unique | 192.168.10.21:2231 |
| | resource identifier), IP(internet | |
| | protocol) address, port number | |
| | mapping, etc.) | |

The receiver may perform the action requested by the sender and transmit a response.

Table 2 illustrates the attributes of the receiver in the header area in the message exchanged for digital twin federation.

TABLE 2

| Attribute | Description | Examples |
|---|---|---|
| Receiver | A value used to uniquely | ailto:John.Doe@example.com |
| ID | identify a receiver | 192.168.10.25:2242 |
| | (e.g., URI(unique resource | |
| | identifier), IP(internet | |
| | protocol) address, port | |
| | number mapping, etc.) | |

Time may refer to creation time of the corresponding message. As an example, it may be expressed as [ISO 8601]. Once that time value is assigned, that information should not change during the lifetime of the message.

Table 3 illustrates the attribute of the time in the header area in messages exchanged for digital twin federation.

TABLE 3

| Attribute | Description | Examples |
|---|---|---|
| Timestamp | A value of creation time | 2022-10-20T03:22:04 + 00:00 |
| | of a message (e.g., date | 2022-10-20T03:22:04Z |
| | and time in UTC(Universal | 20221020T032204Z |
| | Time Coordinated), or date, | 2022-10-20 |
| | etc.) | |

The action field 221 may represent an action or response performed by a digital twin, registry, communication adapter, etc.

Table 4 illustrates the attributes of the action in the data area in messages exchanged for digital twin federation.

TABLE 4

| Attribute | Description | Examples |
|---|---|---|
| Action | A value used to uniquely | Action = GET |
| | identify an action | |
| Result | Values for RESPOND action which | Result = (OK, 1) |
| | contains the result (OK or NOK) | |
| | and the number of objects in | |
| | object field | |

Additionally, an action list may be defined for operations that the digital twin, registry, and communication adapter shall perform or respond to.

Table 5 illustrates a list of actions related to digital twin federation.

TABLE 5

| Attribute | Description |
|---|---|
| CHANGE | Request to a receiver to change the existing data |
| CONNECT | Request to a receiver to connect for digital twin |
| | federation |
| DELETE | Request to a receiver to delete existing data |
| GET | Request to a receiver for sharing data |
| | (Used to among a digital twin, a registry and a |
| | communication adaptor) |
| PROCESS | Request to a receiver for processing functions |
| | (Used to between the digital twins) |
| REGISTER | Request to a receiver to register the data |
| RESPOND | Used to respond which contains the result (OK or NOK) |
| | and the number of objects in the object area |
| SYNC | Publish the new information or change in existing |
| | information by the information owners to subscribers |
| | (Assume that the Pub/sub procedure has already been |
| | performed) |

The object field 222 is required to contain one or more objects that are the target of the action.

Table 6 illustrates the attributes of the object in the data area in messages exchanged for digital twin federation.

TABLE 6

| Attribute | Description | Examples |
|---|---|---|
| Object | The object name for the action | digital twin for traffic |
| | | digital twin for emergency |
| | | medical care |
| | | registry A |
| | | communication adaptor B |
| ID | A value used to uniquely identify | UUID:45256ed6-dd58-47af- |
| | an object | b185-13e8055640ab |
| | (e.g., UUID, URL, URN, etc.) | URL:https://url.kr/e5j79b |
| | | URN:tel:+82-18-123-4567 |
| Description | Represents a description of an | The digital twin for traffic |
| | object consisting of a digital | provides the functions to |
| | twin, registry, communication | find the optimal route and |
| | adapter, etc. | to control traffic signal. |
| | | The digital twin for emergency |
| | | medical care provides the |
| | | function to find the optimal |
| | | medical institution based on |
| | | the number and the status of |
| | | the patients. |
| Data format | Represents a Notation formation | application/xml |
| | for an object | application/json |
| | | text/plain |
| Function | A list of properties for each | Identifier:Func001 |
| property | function provided by a digital twin | Description:find the best route |
| | (e.g., identifier, description, | Parameter:start, destination |
| | parameter, usage examples, etc.) | Example:Func001(A building, |
| | | B hospital) |
| Data | A list of properties for each data | Identifier:ABC Hospital |
| property | provided by the digital twin | Description:general hospital |
| | (e.g., the data identifier, the | Synonyms:clinic, infirmary, |
| | description, the synonyms, the | a doctor's office |
| | contents with a value and value | Contents:value = “5” |
| | unit, etc.) | value unit of measure = |
| | | “number” |
| | | Example: |
| | | value = ResultFunc050(start, |
| | | destination) |
| Connection | A list of value used to access | URL:https://url.kr/5dksr4 |
| information | the object (e.g., URL) | |

Table 6 corresponds to examples of object attributes, and other attributes may be added as needed.

Additionally, an object list may be defined for objects that are targets of actions, such as digital twins, registries, and communication adapters.

Table 7 illustrates a list of objects related to digital twin federation.

TABLE 7

| Attribute | Description | Examples |
|---|---|---|
| Digital twin | A sender or a receiver of data | Object = Digitaltwin |
| | and functions to be shared | ID = “DT-001” |
| | | Description = “Emergency |
| | | medical care” |
| | | Content type = |
| | | “application/xml” |
| | | Function property |
| | | FuncID “Func050” |
| | | Description “searching |
| | | medical institution” |
| | | Parameter = “start, |
| | | destination” |
| | | Example = “Func050(start, |
| | | destination)” |
| | | Data property |
| | | DataID = “Data001” |
| | | Description = “number |
| | | of ambulances” |
| | | Synonym = “emergency |
| | | vehicle” |
| | | Contents value =“” |
| | | value unit of measure = |
| | | “number” |
| | | Connection Information = |
| | | “https://url.kr/ikyrft” |
| Registry | A component registering the feature | Object = Registry |
| | information of each digital twin and | ID = “Reg-005” |
| | providing the registered feature | Description = “Register |
| | information according to the request | the feature information and |
| | from a digital twin | provide the registered |
| | | information” |
| Communication | A component used to establish indirect | Object = Communication |
| adaptor | communication link between digital | adaptor |
| | twins, in case when the digital twins | ID = “CommAdaptor-010” |
| | cannot establish direct communication | Description = “Establish |
| | | indirect communication link |
| | | between digital twins” |

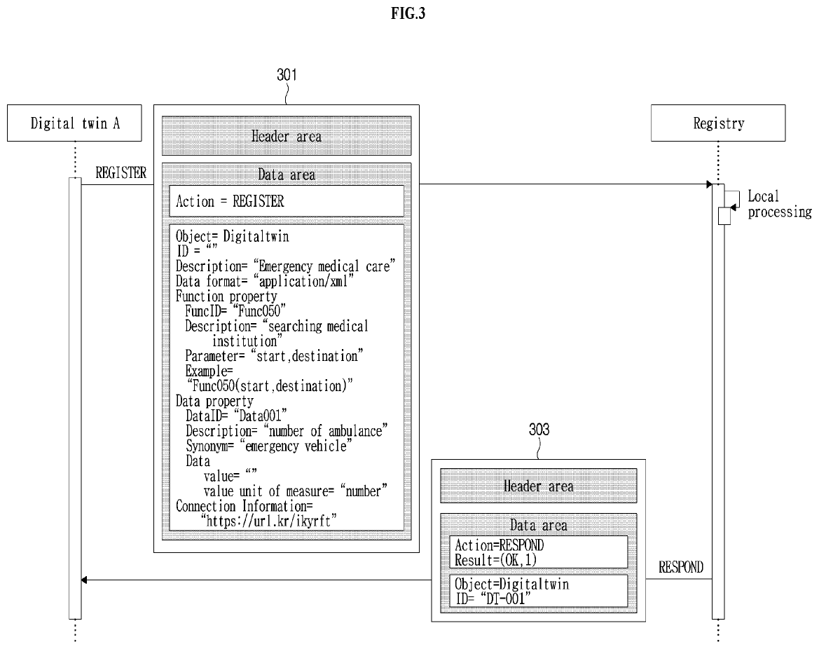

Hereinafter, in the present disclosure, through FIGS. 3 to 11, specific examples of message exchange procedures between components for digital twin federation as described above (e.g., digital twin, registry, and communication adapter, etc.) will be described.

FIG. 3 illustrates a procedure for registering feature information between a digital twin and a registry according to an embodiment of the present disclosure.

Referring to FIG. 3, digital twin A 110 may transmit a message 301 for registering feature information to the registry. The registry may transmit a message 303 in response to this to digital twin A 110.

For example, each of the messages 301 and 303 may be configured to include a header area and a data area (specifically, an action field and an object field) based on the examples of Tables 1 to 7 described above, respectively.

The procedure in FIG. 3 corresponds to an example, and other digital twins in FIG. 1 may also register feature information in the registry in the same manner as the corresponding procedure.

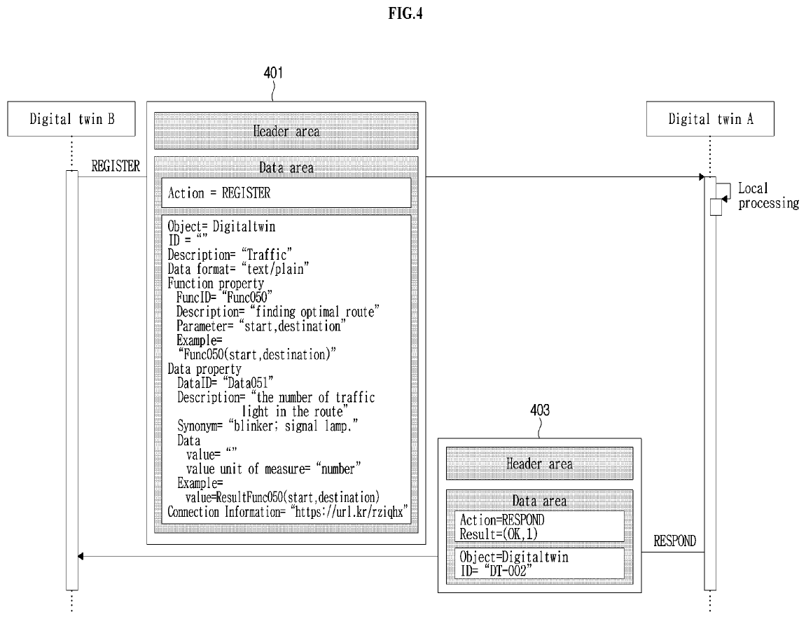

FIG. 4 illustrates a procedure for registering feature information between digital twins according to an embodiment of the present disclosure.

Referring to FIG. 4, digital twin B 120 may transmit a message 401 for registering feature information to digital twin A 110. Digital twin A 110 may transmit a message 403 in response to this to digital twin B 120.

For example, each of the messages 401 and 403 may be configured to include a header area and a data area (specifically, an action field and an object field) based on the examples of Tables 1 to 7 described above, respectively.

Through this procedure, digital twin B 120 may register feature information to digital twin A 110.

The procedure in FIG. 4 corresponds to an example, and other digital twins in FIG. 1 may also register feature information for other digital twins in the same manner as the corresponding procedure.

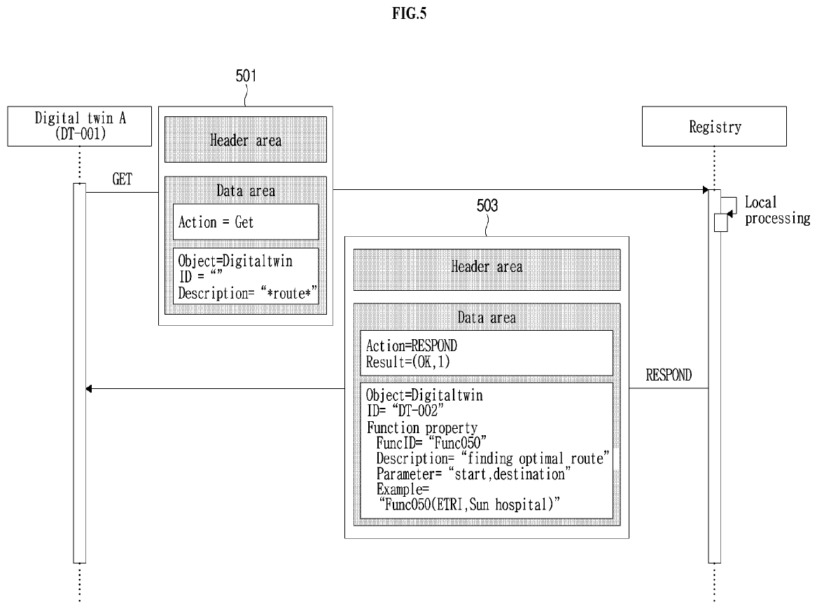

FIG. 5 illustrates a procedure for discovering members of a digital twin federation according to an embodiment of the present disclosure.

Referring to FIG. 5, digital twin A 110 may transmit a message 501 to the registry to request digital twin information with the “*route*” function (i.e., a request for sharing data).

The registry may transmit a message 503 in response to this to digital twin A 110. As an example, the registry may respond to digital twin A 110 with information about “DT-002”.

For example, each of the messages 501 and 503 may be configured to include a header area and a data area (specifically, an action field and an object field) based on the examples of Tables 1 to 7 described above, respectively.

The procedure in FIG. 5 corresponds to an example, and other digital twins in FIG. 1 may also request sharing of certain data in relation to federation member discovery to the registry in the same manner as the corresponding procedure.

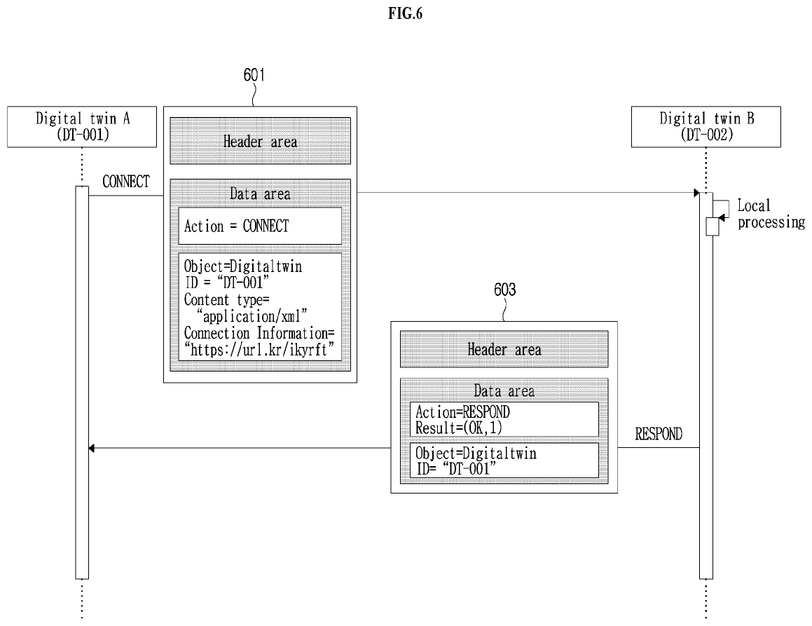

FIG. 6 illustrates a procedure for establishing a direct connection between digital twins according to an embodiment of the present disclosure.

Referring to FIG. 6, digital twin A 110 may transmit a message 601 for direct connection with another digital twin to digital twin B 120. Digital twin B 120 may transmit a message 603 in response to this to digital twin A 110.

For example, each of the messages 601 and 603 may be configured to include a header area and a data area (specifically, an action field and an object field) based on the examples of Tables 1 to 7 described above, respectively.

The procedure in FIG. 6 corresponds to an example, and other digital twins in FIG. 1 may also perform direct connection establishment with other digital twins in the same manner as the corresponding procedure.

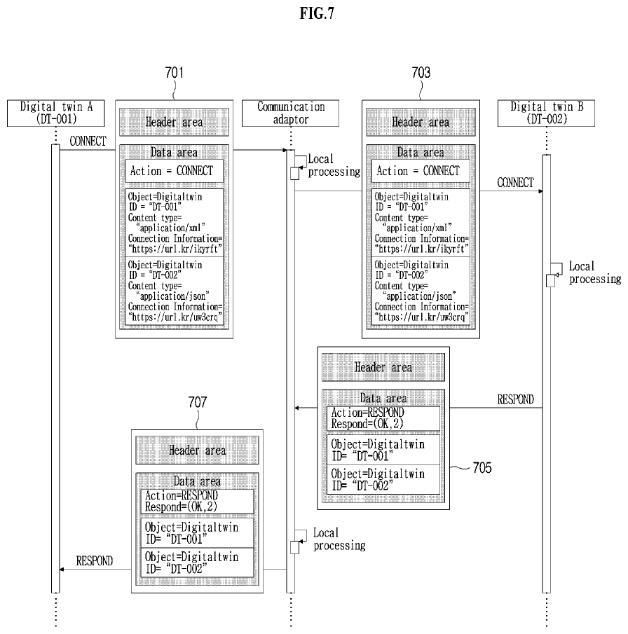

FIG. 7 illustrates a procedure for establishing an indirect connection using a communication adapter between digital twins according to an embodiment of the present disclosure.

Referring to FIG. 7, digital twin A 110 may transmit a message 701 for indirect connection with another digital twin to a communication adapter. Afterwards, the communication adapter may transmit a message 703 for the corresponding indirect connection to digital twin B 120.

In this regard, the message 701 and the message 703 may be set identically in the information contained in the data area (e.g., action-related information, object-related information, etc.), and the information contained in the header area (e.g., sender, receiver, time, etc.) may be set differently.

Digital twin B 120 may transmit a message 705 in response to the above-described indirect connection request to the communication adapter. Afterwards, the communication adapter may transmit a message 707 for the corresponding response to digital twin A 110.

In this regard, the message 705 and the message 707 may be set identically in the information included in the data area (e.g., action-related information, object-related information, etc.), and the information included in the header area (e.g., sender, receiver, time, etc.) may be set differently.

For example, each of the messages 701, 703, 705, and 707 includes a header area and a data area (specifically, an action field and an object field) based on the examples in Tables 1 to 7 described above, respectively.

The procedure in FIG. 7 corresponds to an example, and another digital twin in FIG. 1 may also establish an indirect connection with another digital twin in the same manner as the corresponding procedure.

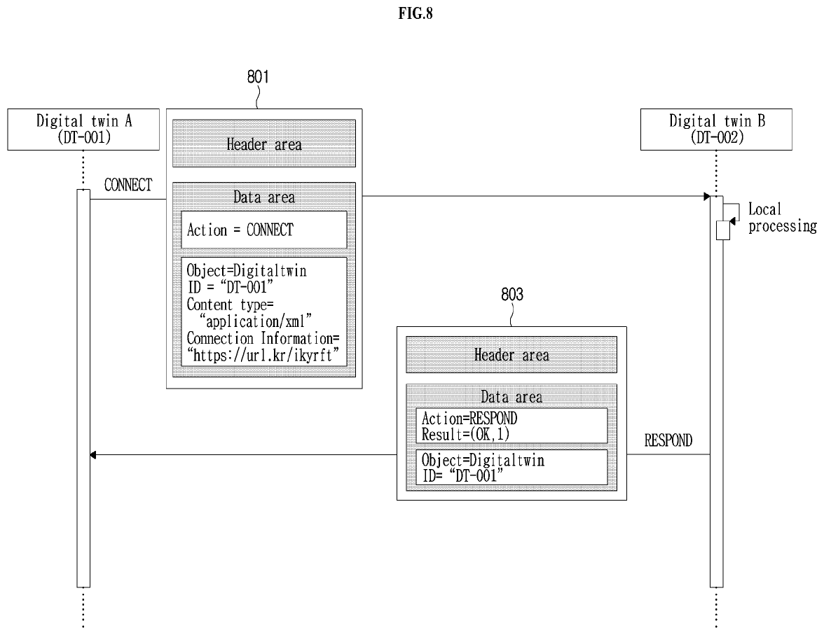

FIG. 8 illustrates a direct information exchange procedure between digital twins according to an embodiment of the present disclosure.

Referring to FIG. 8, digital twin A 110 may transmit a message 801 for direct information exchange with another digital twin to digital twin B 120. Digital twin B 120 may transmit a message 803 in response to this to digital twin A 110.

For example, each of the messages 801 and 803 may be configured to include a header area and a data area (specifically, an action field and an object field) based on the examples of Tables 1 to 7 described above, respectively.

The procedure in FIG. 8 corresponds to an example, and other digital twins in FIG. 1 may also perform direct connection establishment with other digital twins in the same manner as the corresponding procedure.

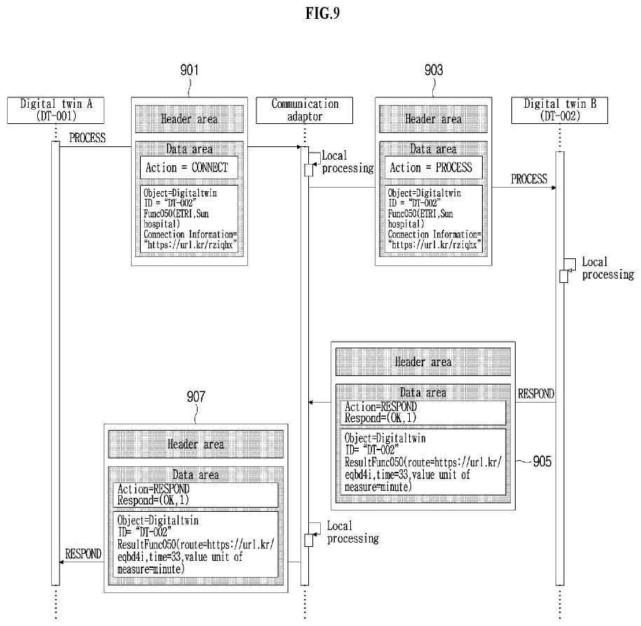

FIG. 9 illustrates an indirect information exchange procedure for converting content types between digital twins according to an embodiment of the present disclosure.

Referring to FIG. 9, digital twin A 110 may transmit a message 901 for indirectly exchanging information to a communication adapter to convert content types between different digital twins. Afterwards, the communication adapter may transmit a message 903 for indirect information exchange to digital twin B 120.

In this regard, the message 901 and the message 903 may be set identically in the information contained in the data area (e.g., action-related information, object-related information, etc.), and the information contained in the header area (e.g., sender, receiver, time, etc.) may be set differently.

Digital twin B 120 may transmit a message 905 in response to the above-described indirect information exchange request to the communication adapter. Afterwards, the communication adapter may transmit a message 907 for the corresponding response to digital twin A 110.

In this regard, the message 905 and the message 907 may be set identically in the information contained in the data area (e.g., action-related information, object-related information, etc.), and the information contained in the header area (e.g., sender, receiver, time, etc.) may be set differently.

For example, each of the messages 901, 903, 905, and 907 may be configured to include a header area and a data area (specifically, an action field and an object field) based on the examples in Tables 1 to 7 described above, respectively.

The procedure in FIG. 9 corresponds to an example, and another digital twin in FIG. 1 may also establish an indirect connection with another digital twin in the same manner as the corresponding procedure.

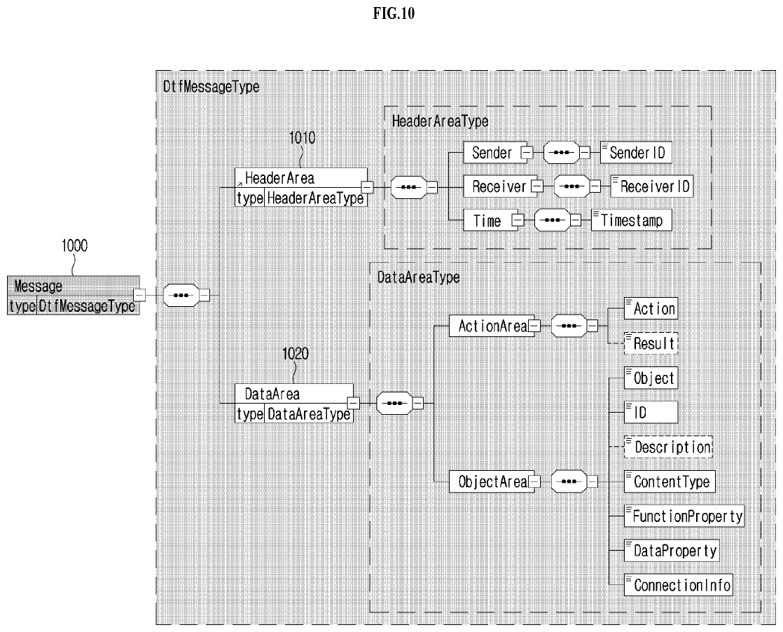

FIG. 10 illustrates an XML schema diagram of a message structure according to an embodiment of the present disclosure.

Referring to the XML schema diagram in FIG. 10, a message 1000 related to digital twin federation according to an embodiment of the present disclosure may be composed of a header area 1010 and a data area 1020.

Specifically, the header area 1010 may be composed of a sender, a receiver, and time.

Here, the sender may be composed of sender ID information, the receiver may be composed of receiver ID information, and the time may be composed of timestamp information.

The data area 1020 may be composed of an action field (e.g., ActionArea) and an object area (e.g., ObjectArea).

Here, the action field may be composed of one or more of Action and Result. An object field may be composed of one of Object, ID, Description, ContentType, FunctionProperty, DataProperty, and ConnectionInfo (i.e., access-related information).

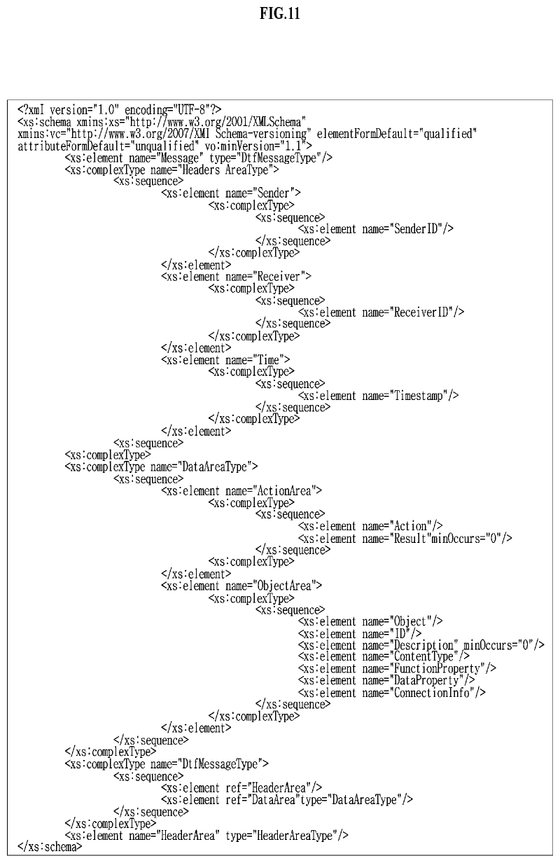

In this regards, FIG. 11 illustrates an XML schema of a message structure according to an embodiment of the present disclosure.

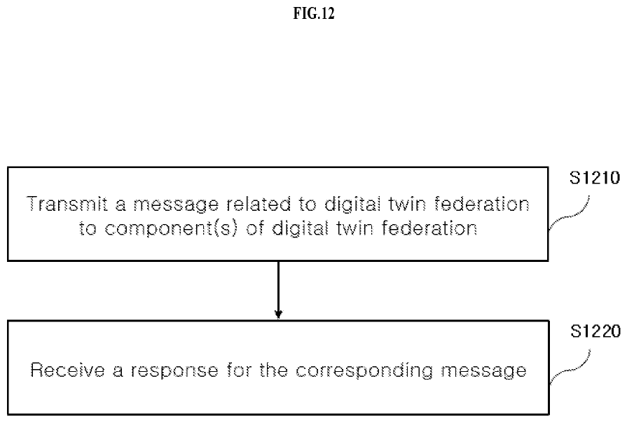

FIG. 12 illustrates an operational flowchart of a method for exchanging digital twin association information according to an embodiment of the present disclosure.

The procedure in FIG. 12 may be based on the method of setting up a digital twin federation and exchanging information/data described above in the present disclosure.

Digital twin federation may correspond to a method of providing new services based on sharing data and/or functions between multiple digital twins.

The digital twin (e.g., digital twin A) may transmit a message related to the digital twin federation to a component of the digital twin federal (Step S1210).

Herein, the corresponding component of the digital twin federation may correspond to one or more of another digital twin (e.g., digital twin B), a registry, or a communication adapter.

Additionally, the message may include a header area and a data area. Herein, the data area may include object information related to at least one of the digital twin or the component of the digital twin federation (e.g., object field in the present disclosure) and action information indicating an operation related to the digital twin federation (e.g., action field in the present disclosure).

In relation to the foregoing message, the header area may include at least one of sender identification information, receiver identification information, or creation time-related information for the message.

Additionally, the action information may indicate one of the action list predefined for the digital twin federation. As an example, the predefined action list may include one or more of 1) request for change of existing data, 2) request for connecting for digital twin federation, 3) request for deleting of existing data, 4) request for sharing data, 5) request for processing function, 6) request for registering data, 7) a response, or 8) publishing of changes to information.

Additionally, the object information may include information on attributes for objects related to the digital twin federation. As an example, the attributes for the object may include one or more of 1) name of an object, 2) identification information of an object, 3) description of an object, 4) notation formation for an object, 5) function property, 6) data property, 7) content type, or 8) access-related information.

After, the digital twin may receive a response to the message of the Step S1210 (Step S1220).

In this regard, when the message of the Step S1210 corresponds to a message for registering feature information of the digital twin with the registry, the corresponding message may be transmitted to the registry. In contrast, when the message of the Step S1210 corresponds to a message for registering feature information of the digital twin to the other digital twin, the corresponding message may be transmitted to the another digital twin.

Additionally or alternatively, when the message of the Step S1210 corresponds to a message for discovering members for the digital twin federation, the corresponding message may be set to request information on a digital twin with one or more of specific data, a specific function, or specific performance and is sent to the registry. In this case, the response of the Step S1220 may include identification information on the digital twin with a specific function.

Additionally or alternatively, when the message of the Step S1210 corresponds to a message for establishing a connection or data and function processing with the other digital twin, and direct communication between the digital twin and the another digital twin is possible, the corresponding message may be transmitted to the another digital twin. In contrast, when the message of the Step S1210 corresponds to a message for establishing a connection or data and function processing with the other digital twin, and direct communication between the digital twin and the another digital twin is impossible, the corresponding message may be transmitted to the communication adapter and transferred to the another digital twin.

Additionally or alternatively, the response of the Step S1220 may include one or more of 1) information for identifying an operation based on the message, or 2) information on a result of the operation and the number of objects according to the object information.

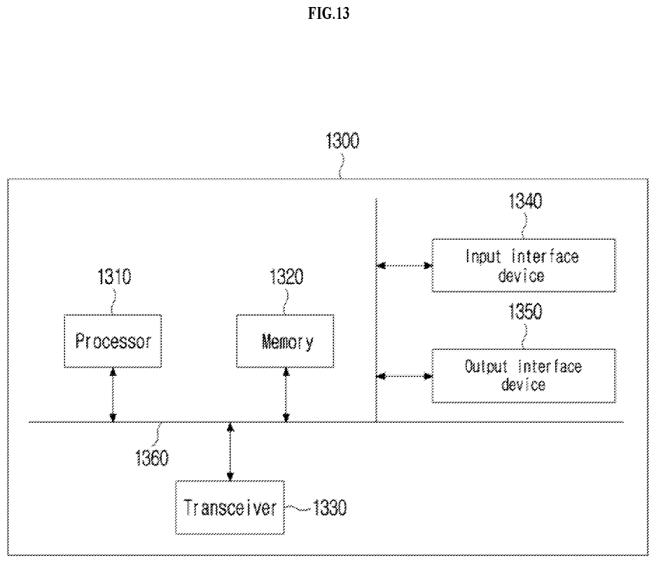

FIG. 13 is a block diagram illustrating an apparatus according to an embodiment of the present disclosure.

Referring to FIG. 13, a device 1300 may represent a device that implements the method for exchanging information/message for digital twin federation described in the present disclosure is implemented.

For example, the device 1300 may generally support/perform the function of registering feature information, the function of discovering/searching federation members, the function of establishing a connection with another digital twin, the function of exchanging information, etc.

The device 1300 may include at least one of a processor 1310, a memory 1320, a transceiver 1330, an input interface device 1340, and an output interface device 1350. Each of the components may be connected by a common bus 1360 to communicate with each other. In addition, each of the components may be connected through a separate interface or a separate bus centering on the processor 1310 instead of the common bus 1360.

The processor 1310 may be implemented in various types such as an application processor (AP), a central processing unit (CPU), a graphic processing unit (GPU), etc., and may be any semiconductor device that executes a command stored in the memory 1320. The processor 1310 may execute a program command stored in the memory 1320. The processor 1310 may be configured to implement a method/system for exchanging information/message for digital twin federation based on FIGS. 1 to 12 described above.

And/or, the processor 1310 may store a program command for implementing at least one function for the corresponding modules in the memory 1320 and may control the operation described based on FIGS. 1 to 12 to be performed.

The memory 1320 may include various types of volatile or non-volatile storage media. For example, the memory 1320 may include read-only memory (ROM) and random access memory (RAM). In an embodiment of the present disclosure, the memory 1320 may be located inside or outside the processor 1310, and the memory 1320 may be connected to the processor 1310 through various known means.

The transceiver 1330 may perform a function of transmitting and receiving data processed/to be processed by the processor 1310 with an external device and/or an external system.

The input interface device 1340 is configured to provide data to the processor 1310.

The output interface device 1350 is configured to output data from the processor 1310.

According to the present disclosure, a method and apparatus for exchanging information for digital twin federation may be provided.

According to the present disclosure, a method and apparatus for exchanging information between digital twin components to provide, through a digital twin federation, new services across multiple domains, such as registering feature information between components such as digital twins, registries, and communication adapters for digital twin federation, searching digital twins for federation targets, establishing connections, and exchanging information may be provided.

According to the present disclosure, a method and apparatus for exchanging information for digital twin federation to provide a new service, by sharing data and functions by combining two or more digital twins used in each domain such as manufacturing, city, home, energy, and medical fields may be provided.

The components described in the example embodiments may be implemented by hardware components including, for example, at least one digital signal processor (DSP), a processor, a controller, an application-specific integrated circuit (ASIC), a programmable logic element, such as an FPGA, GPU other electronic devices, or combinations thereof. At least some of the functions or the processes described in the example embodiments may be implemented by software, and the software may be recorded on a recording medium. The components, the functions, and the processes described in the example embodiments may be implemented by a combination of hardware and software.

The method according to example embodiments may be embodied as a program that is executable by a computer, and may be implemented as various recording media such as a magnetic storage medium, an optical reading medium, and a digital storage medium.

Various techniques described herein may be implemented as digital electronic circuitry, or as computer hardware, firmware, software, or combinations thereof. The techniques may be implemented as a computer program product, i.e., a computer program tangibly embodied in an information carrier, e.g., in a machine-readable storage device (for example, a computer-readable medium) or in a propagated signal for processing by, or to control an operation of a data processing apparatus, e.g., a programmable processor, a computer, or multiple computers.

A computer program(s) may be written in any form of a programming language, including compiled or interpreted languages and may be deployed in any form including a stand-alone program or a module, a component, a subroutine, or other units suitable for use in a computing environment. A computer program may be deployed to be executed on one computer or on multiple computers at one site or distributed across multiple sites and interconnected by a communication network.

Processors suitable for execution of a computer program include, by way of example, both general and special purpose microprocessors, and any one or more processors of any kind of digital computer. Generally, a processor will receive instructions and data from a read-only memory or a random access memory or both. Elements of a computer may include at least one processor to execute instructions and one or more memory devices to store instructions and data. Generally, a computer will also include or be coupled to receive data from, transfer data to, or perform both on one or more mass storage devices to store data, e.g., magnetic, magneto-optical disks, or optical disks. Examples of information carriers suitable for embodying computer program instructions and data include semiconductor memory devices, for example, magnetic media such as a hard disk, a floppy disk, and a magnetic tape, optical media such as a compact disk read only memory (CD-ROM), a digital video disk (DVD), etc. and magneto-optical media such as a floptical disk, and a read only memory (ROM), a random access memory (RAM), a flash memory, an erasable programmable ROM (EPROM), and an electrically erasable programmable ROM (EEPROM) and any other known computer readable medium. A processor and a memory may be supplemented by, or integrated into, a special purpose logic circuit.

The processor may run an operating system (OS) and one or more software applications that run on the OS. The processor device also may access, store, manipulate, process, and create data in response to execution of the software. For purpose of simplicity, the description of a processor device is used as singular; however, one skilled in the art will be appreciated that a processor device may include multiple processing elements and/or multiple types of processing elements. For example, a processor device may include multiple processors or a processor and a controller. In addition, different processing configurations are possible, such as parallel processors.

Also, non-transitory computer-readable media may be any available media that may be accessed by a computer, and may include both computer storage media and transmission media.

The present specification includes details of a number of specific implements, but it should be understood that the details do not limit any invention or what is claimable in the specification but rather describe features of the specific example embodiment.

Features described in the specification in the context of individual example embodiments may be implemented as a combination in a single example embodiment. In contrast, various features described in the specification in the context of a single example embodiment may be implemented in multiple example embodiments individually or in an appropriate sub-combination. Furthermore, the features may operate in a specific combination and may be initially described as claimed in the combination, but one or more features may be excluded from the claimed combination in some cases, and the claimed combination may be changed into a sub-combination or a modification of a sub-combination.

Similarly, even though operations are described in a specific order on the drawings, it should not be understood as the operations needing to be performed in the specific order or in sequence to obtain desired results or as all the operations needing to be performed. In a specific case, multitasking and parallel processing may be advantageous. In addition, it should not be understood as requiring a separation of various apparatus components in the above described example embodiments in all example embodiments, and it should be understood that the above-described program components and apparatuses may be incorporated into a single software product or may be packaged in multiple software products.

It should be understood that the example embodiments disclosed herein are merely illustrative and are not intended to limit the scope of the invention. It will be apparent to one of ordinary skill in the art that various modifications of the example embodiments may be made without departing from the spirit and scope of the claims and their equivalents.

Accordingly, it is intended that this disclosure embrace all other substitutions, modifications and variations belong within the scope of the following claims.

What is claimed is:

1. A method of transmitting and receiving information for a digital twin federation by a digital twin, the method comprising:
transmitting a message related to the digital twin federation to a component of the digital twin federal; and
receiving a response to the message,
wherein the component of the digital twin federation correspond to one or more of another digital twin, a registry, or a communication adapter,
wherein the message include a header area and a data area, and
wherein the data area includes object information related to at least one of the digital twin or the component of the digital twin federation and action information indicating an operation related to the digital twin federation.

2. The method of claim 1,
wherein the digital twin federation is based on sharing one or more of data or a function between the digital twin and the another digital twin.

3. The method of claim 1,
wherein the header area includes at least one of sender identification information, receiver identification information, or creation time-related information for the message.

4. The method of claim 1,
wherein the action information indicates one of the action list predefined for the digital twin federation, and
wherein the predefined action list includes one or more of 1) request for change of existing data, 2) request for connecting for digital twin federation, 3) request for deleting of existing data, 4) request for sharing data, 5) request for processing function, 6) request for registering data, 7) a response, or 8) publishing of changes to information.

5. The method of claim 1,
wherein the object information includes information on attributes for objects related to the digital twin federation, and
wherein the attributes for the object include one or more of 1) name of an object, 2) identification information of an object, 3) description of an object, 4) notation formation for an object, 5) function property, 6) data property, 7) content type, or 8) access-related information.

6. The method of claim 1,
wherein, when the message corresponds to a message for registering feature information of the digital twin with the registry, the message is transmitted to the registry and
wherein, when the message corresponds to a message for registering feature information of the digital twin to the another digital twin, the message is transmitted to the another digital twin.

7. The method of claim 1,
wherein, when the message corresponds to a message for discovering members for the digital twin federation, the message is set to request information on a digital twin with one or more of specific data, a specific function, or specific performance and is sent to the registry, and
wherein the response includes identification information on the digital twin with one or more of specific data, a specific function, or specific performance.

8. The method of claim 1,
wherein, when the message corresponds to a message for establishing a connection or data and function processing with the another digital twin, and direct communication between the digital twin and the another digital twin is possible, the message is transmitted to the another digital twin, and
wherein, when the message corresponds to a message for establishing a connection or data and function processing with the another digital twin, and direct communication between the digital twin and the another digital twin is impossible, the message is transmitted to the communication adapter and transferred to the another digital twin.

9. The method of claim 1,
wherein the response includes one or more of 1) information for identifying an operation based on the message, or 2) information on a result of the operation and the number of objects according to the object information.

10. An apparatus for transmitting and receiving information for a digital twin federation by a digital twin, the apparatus comprising:
a processor and a memory,
wherein the processor is configured to:
transmit a message related to the digital twin federation to a component of the digital twin federal; and
receive a response to the message,
wherein the component of the digital twin federation correspond to one or more of another digital twin, a registry, or a communication adapter,
wherein the message include a header area and a data area, and
wherein the data area includes object information related to at least one of the digital twin or the component of the digital twin federation and action information indicating an operation related to the digital twin federation.

11. The apparatus of claim 10,
wherein the digital twin federation is based on sharing one or more of data or a function between the digital twin and the another digital twin.

12. The apparatus of claim 10,
wherein the header area includes at least one of sender identification information, receiver identification information, or creation time-related information for the message.

13. The apparatus of claim 10,
wherein the action information indicates one of the action list predefined for the digital twin federation, and
wherein the predefined action list includes one or more of 1) request for change of existing data, 2) request for connecting for digital twin federation, 3) request for deleting of existing data, 4) request for sharing data, 5) request for processing function, 6) request for registering data, 7) a response, or 8) publishing of changes to information.

14. The apparatus of claim 10,
wherein the object information includes information on attributes for objects related to the digital twin federation, and
wherein the attributes for the object include one or more of 1) name of an object, 2) identification information of an object, 3) description of an object, 4) notation formation for an object, 5) function property, 6) data property, 7) content type, or 8) access-related information.

15. The apparatus of claim 10,
wherein, when the message corresponds to a message for registering feature information of the digital twin with the registry, the message is transmitted to the registry and
wherein, when the message corresponds to a message for registering feature information of the digital twin to the another digital twin, the message is transmitted to the another digital twin.

16. The apparatus of claim 10,
wherein, when the message corresponds to a message for discovering members for the digital twin federation, the message is set to request information on a digital twin with one or more of specific data, a specific function, or specific performance and is sent to the registry, and
wherein the response includes identification information on the digital twin with one or more of specific data, a specific function, or specific performance.

17. The apparatus of claim 10,
wherein, when the message corresponds to a message for establishing a connection or data and function processing with the another digital twin, and direct communication between the digital twin and the another digital twin is possible, the message is transmitted to the another digital twin, and
wherein, when the message corresponds to a message for establishing a connection or data and function processing with the another digital twin, and direct communication between the digital twin and the another digital twin is impossible, the message is transmitted to the communication adapter and transferred to the another digital twin.

18. The apparatus of claim 10,
wherein the response includes one or more of 1) information for identifying an operation based on the message, or 2) information on a result of the operation and the number of objects according to the object information.

19. One or more non-transitory computer readable media storing one or more instructions,
wherein the one or more instructions are executed by one or more processors and control an apparatus for processing hologram to:
transmit a message related to the digital twin federation to a component of the digital twin federal; and
receive a response to the message,
wherein the component of the digital twin federation correspond to one or more of another digital twin, a registry, or a communication adapter,
wherein the message include a header area and a data area, and
wherein the data area includes object information related to at least one of the digital twin or the component of the digital twin federation and action information indicating an operation related to the digital twin federation.

20. The computer readable media of claim 19,
wherein the digital twin federation is based on sharing one or more of data or a function between the digital twin and the another digital twin.
